(19) United States
(12) Patent Application Publication
(10) Pub. No.: US 2024/0213348 A1
(43) Pub. Date: Jun. 27, 2024

(54) PLANAR COMPLEMENTARY MOSFET STRUCTURE TO REDUCE LEAKAGES AND PLANAR AREAS

(71) Applicant: Invention And Collaboration Laboratory, Inc., Taipei City (TW)

(72) Inventor: Chao-Chun LU, Hsinchu (TW)

(73) Assignee: Invention And Collaboration Laboratory, Inc., Taipei City (TW)

(21) Appl. No.: 18/422,360

(22) Filed: Jan. 25, 2024

Related U.S. Application Data
(63) Continuation-in-part of application No. 18/203,688, filed on May 31, 2023.
(60) Provisional application No. 63/348,050, filed on Jun. 2, 2022.
(60) Provisional application No. 63/618,930, filed on Jan. 9, 2024.

(51) Int. Cl. H01L 29/49; H01L 21/28; H01L 29/78

(52) U.S. Cl. CPC H01L 29/4916; H01L 21/28035; H01L 29/7833

(57) ABSTRACT

The present invention discloses a planar CMOSFET structure used in the peripheral circuit of DRAM chip and in sense amplifiers of array core circuit of DRAM chip, the planar CMOSFET structure comprises a planar P type MOSFET with a first conductive region, a planar N type MOSFET with a second conductive region, and a cross-shape localized isolation region between the planar P type MOSFET and the planar N type MOSFET; wherein the cross-shape localized isolation region includes a horizontally extended isolation region contacts to a bottom side of the first conductive region and a bottom side of the second conductive region. The present invention could be similarly applied to the transistors for CMOS logic circuits as well.

This invention is a continuation-in-part of U.S. patent application Ser. No. filed on 18/203,688 filed on May 31, 2023 with title of “Planar Complementary MOSFET Structure to Reduce Leakages and Planar Areas”, which claims the priority of U.S. Provisional Application No. 63/348,050 filed on Jun. 2, 2022 with title of “Planar Complementary MOSFET Structure to Reduce Leakages and Planar Areas” and also claims the priority of U.S. Provisional Application No. 63/618,930 filed on Jan. 9, 2024 with title of “Transistor having Silicon Gate with High Dopant Activation Concentration”. The whole content of which are incorporated by reference herein.

### BACKGROUND OF THE INVENTION

### 1. Field of the Invention

The present invention relates to a new planar transistor and a planar Complementary MOSFET (CMOS) structure, and particularly to the planar transistor and/or the planar Complementary MOSFET (CMOS) structure utilized in peripheral circuit or sense amplifiers of DRAM that can reduce current leakage, reduce short channel effect, and prevent latch-up.

### 2. Description of the Prior Art

Although advanced technology nodes (such as 3-7 nm) are frequently used in high performance computing applications (such as Artificial Intelligence AI, CPU, GPU, etc.), the mature technology nodes (such as 20˜30 nm) are still popular in many IC applications, such as power management IC, MCU, or DRAM chip. Using DRAM as an example, nowadays most customized DRAMs are still manufactured by the mature technology nodes (such as 12˜30 nm), and all transistors in DRAM chip 17 (as shown in FIG. 1A), including those in peripheral circuit 171 (at least including data/address I/O circuits, address decoders, command logic, and refresh circuits, etc.) and those in array core circuit 172 (including storage memory arrays, sense amplifiers, etc.) are still planar transistors.

FIG. 1B shows a cross-section view of a state-of-the-art planar Complementary Metal-Oxide-Semiconductor Field-Effect Transistors (CMOSFETs) 10 which are most widely used in the peripheral circuit of DRAM chip and in sense amplifiers of array core circuit of DRAM chip. The CMOSFETs 10 includes a planar NMOS transistor 11 and a planar PMOS transistor 12, wherein a Shallow Trench Isolation (STI) region 13 is positioned between the NMOS transistor 11 and the PMOS transistor 12. The gate structure 14 of the NMOS transistor 11 or the PMOS transistor 12 using some conductive material (like metal, polysilicon or polyside, etc.) over an insulator (such as oxide, oxide/nitride or some high-k dielectric, etc.) is formed on top of the CMOS whose sidewalls are isolated from those of other transistors by using insulation materials (e.g. oxide or oxide/nitride or other dielectrics). For the planar NMOS transistor 11 there are source and drain regions which are formed by an Ion-implantation plus Thermal Annealing technique to implant n-type dopants into a p-type substrate (or a p-well) which thus results in two separated n+/p junction areas. For the planar PMOS transistor 12 both source and drain regions are formed by ion-implanting p-type dopants into an n-well which thus results in two p+/n junction areas. Furthermore, to lessen impact ionization and hot carrier injection prior to highly doped n+/p or p+/n junction, it is common to form a lightly doped-drain (LDD) region 15 under the gate structure.

On one hand, during the previously mentioned thermal annealing process, the implanted n-type or p-type dopants in the CMOSFETs 10 will unavoidably diffuse into different directions and enlarge the area of the source and drain regions. Moreover, another thermal annealing process will happen during the formation of capacitors over the access transistors in the array core circuit of DRAM chip to reduce the connecting resistance between the capacitor and the access transistor. Such second thermal annealing process again causes the diffusion of n-type or p-type dopants and increases the area of the source and drain regions. The larger the area of the source and drain regions due to the thermal annealing processes, the shorter of the effective channel length (Leff shown in FIG. 1B) between the source and drain regions, and such reduced effective channel length Leff will incur Short Channel Effects (SCE). Therefore, to reduce the impact of SCE, it is common to reserve longer gate length to accommodate the diffusion of n-type or p-type dopants due to thermal annealing. Using technology node (λ) of 25 nm as an example, the reserved gate length would be around 100 nm, almost four times of the technology node λ.

On the other hand, since the NMOS transistor 11 and the PMOS transistor 12 are located respectively inside some adjacent regions of p-substrate and n-well which have been formed next to each other within a close neighborhood, a parasitic junction structure called n+/p/n/p+ (the path marked by dash line in FIG. 1B is called as n+/p/n/p+ Latch-up path) parasitic bipolar device is formed with its contour starting from the n+ region of the NMOS transistor 11 to the p-well to the neighboring n-well and further up to the p+ region of the PMOS transistor 12.

Once there are significant noises occurred on either n+/p junctions or p+/n junctions, an extraordinarily large current may flow through this n+/p/n/p+ junction abnormally which can possibly shut down some operations of CMOS circuits and to cause malfunction of the entire chip. Such an abnormal phenomenon called Latch-up is detrimental for CMOS operations and must be avoided. One way to increase the immunity to Latch-up which is certainly a weakness for CMOS is to increase the distance from n+ region to the p+ region (labeled as Latch-up Distance in FIG. 1B) and both n+ and p+ regions must be designed to be isolated by some vertically oriented oxide (or other suitable insulator materials) as isolation regions which is usually the STI (Shallow Trench Isolation) region 13. Using technology node (λ) of 25 nm as an example, the reserved Latch-up Distance would be around 500 nm, almost 20 times of the technology node λ. More serious efforts to avoid Latch-up must design a guard-band structure which further increases the distance between n+ regions and p+ regions and/or must add extra n+ regions or p+ regions to collect abnormal charges from noise sources. These isolation schemes always increase extra planar areas to sacrifice the die size of CMOS circuits.

Other problems are introduced or getting worse in current DRAM design with planar transistors or CMOSFETs:

(1) All junction leakages resulted by junction formation processes such as forming LDD (Lightly Doped Drain) structure into the substrate/well regions, n+ Source/Drain structures into p-substrate and p+ Source/Drain structures into n-well are getting worse to control since leakage currents occur through both perimeter and bottom areas where extra damages like vacant traps for holes and electrons are harder to be repaired due to lattice imperfections which have been created by ion-implantation.

(2) In addition, since the ion-implantation to form the LDD structure (or the n+/p junction or the p+/n junction) works like bombardments in order to insert ions from the top of a silicon surface straight down to the substrate, it is hard to create uniform material interfaces with lower defects from the Source and Drain regions to the channel and the substrate-body regions since the dopant concentrations are non-uniformly distributed vertically from the top surface with higher doping concentrations down to the junction regions with lower doping concentrations.

(3) It's getting harder to align the LDD junction edge to the edge of gate structure of the transistor in a perfect position by only using the conventional self-alignment method of using gate, spacer and ion-implantation formation. In addition, the Thermal Annealing process for removing the ion-implantation damages must count on high temperature processing techniques such as Rapid

Thermal Annealing method by using various energy sources or other thermal processes. One problem thus created is that a Gate-induced Drain Leakage (GIDL) current. As shown in FIG. 1C (cited from: A. Sen and J. Das, “MOSFET GIDL Current Variation with Impurity Doping Concentration—A Novel Theoretical Approach” IEEE ELECTRON DEVICE LETTERS,VOL.38,NO.5,MAY 2017), the MOSFET structure with a thin oxide which close to the Gate and Drain/Source region exists parasitic Metal-Gated-Diode, and the GIDL issued is induced due to the parasitic Metal-Gated-Diode formed in the Gate-to-Source/Drain regions and hard to be controlled regardless the fact that it should be minimized to reduce leakage currents; the other problem as created is that the effective channel length is difficult to be controlled and so the SCE is hard to be minimized.

(4) Since the vertical length of STI structures is harder to be made deeper while the planar width of the device isolation must be scaled down (otherwise a worse depth-to-opening aspect ratio were created for integrated processes of making etching, filling and planarization), the proportional ratio of the planar isolation distance between the n+ and p+ regions of the neighbor transistors which is reserved for preventing Latch-up to the shrunken λ can not be reduced but increased so as to hurt the die area reduction when scaling down CMOS devices.

### SUMMARY OF THE INVENTION

This invention discloses several new concepts of realizing a novel planar transistor and planar CMOSFET structure, especially used in the peripheral circuit of DRAM chip and in sense amplifiers of array core circuit of DRAM chip, which greatly improves or even solved most of the problems as stated above, such as minimizing current leakages, increasing channel-conduction performance and control, optimizing functions of source and drain regions such as making better their conductance to metal interconnections and their closest physical intact to the channel region with a seamless orderly crystalline Lattice matchup, increasing higher immunity of CMOS circuits against Latch-up and minimizing the planar area used for layout isolations between NMOS and PMOS in order to avoid Latch-Up.

According to one object of the invention, the DRAM chip or circuit comprises a semiconductor substrate with a semiconductor surface, an array core circuit with a sense amplifier circuit and a plurality of DRAM cells electrically coupled to the sense amplifier circuit, and a peripheral circuit electrically coupled to the array core circuit. Wherein, either the sense amplifier circuit or the peripheral circuit has a complementary MOSFET structure, the complementary MOSFET structure comprises a planar P type MOSFET comprising a first conductive region, a planar N type MOSFET comprising a second conductive region, and a cross-shape localized isolation region between the planar P type MOSFET and the planar N type MOSFET. Wherein the cross-shape localized isolation region includes a horizontally extended isolation region below the semiconductor surface, and the horizontally extended isolation region contacts to a bottom side of the first conductive region and a bottom side of the second conductive region.

According to one aspect of the invention, the complementary MOSFET structure further comprises a first concave formed below the semiconductor surface, and the first concave accommodates the first conductive region.

According to one aspect of the invention, the first conductive region comprises an undoped semiconductor region and/or a lightly doped semiconductor region which is independent from the semiconductor substrate.

According to one aspect of the invention, the undoped semiconductor region or the lightly doped semiconductor region abuts against a channel region of the planar P type MOSFET.

According to one aspect of the invention, the first conductive region further comprises a heavily doped semiconductor region, wherein the heavily doped semiconductor region is positioned in the first trench, and the lightly doped semiconductor region and the heavily doped semiconductor region are formed with same lattice structure.

According to one aspect of the invention, the first conductive region further comprising a metal region, the metal region is positioned in the first concave and abuts against the heavily doped semiconductor region.

According to one aspect of the invention, the complementary MOSFET structure further comprises a first concave formed below the semiconductor surface, the first concave accommodates a first portion of the horizontally extended isolation region.

According to one aspect of the invention, the planar P type MOSFET further comprises a gate region over the semiconductor surface, and an edge of the gate region is aligned or substantially aligned with an edge of the first conductive region.

According to one aspect of the invention, the planar P type MOSFET further comprises a gate region, and the entire first portion of the horizontally extended isolation region is not directly underneath the gate structure.

According to one aspect of the invention, the planar P type MOSFET further comprises a gate region, and less than 5% of the first portion of the horizontally extended isolation region is directly underneath the gate structure.

According to one aspect of the invention, the horizontally extended isolation region is a composite isolation region.

According to one aspect of the invention, the composite isolation region includes an oxide layer and a Nitride layer over the oxide layer.

According to one aspect of the invention, a vertical depth of the oxide layer is smaller than that of the Nitride layer.

According to one aspect of the invention, the horizontally extended isolation region includes a first horizontally extended isolation region and a second horizontally extended isolation region, the bottom side of the first conductive region is shielded from the semiconductor substrate by the first horizontally extended isolation region, and the bottom side of the second conductive region is shielded from the semiconductor substrate by the second horizontally extended isolation region.

According to one aspect of the invention, the cross-shape localized isolation region includes a vertically extended isolation region between the first horizontally extended isolation region and the second horizontally extended isolation region, wherein a vertical depth of the vertically extended isolation region is higher than a sum of a vertical depth of the first second horizontally extended isolation region and a vertical depth of the first conductive region.

According to another object of the invention, a DRAM circuit formed by a technology node λ according to the present invention comprises a semiconductor substrate with a semiconductor surface, an array core circuit with a sense amplifier circuit and a plurality of DRAM cells coupled to the sense amplifier circuit, and a peripheral circuit electrically coupled to the array core circuit. Wherein either the sense amplifier circuit or the peripheral circuit has a complementary MOSFET structure, the complementary MOSFET structure comprises a planar P type MOSFET comprising a first source region, a first drain region and a first gate region over the semiconductor surface, and a planar N type MOSFET comprising a second source region, a second drain region and a second gate region over the semiconductor surface. Wherein the first source region or the first drain region includes a lightly doped semiconductor region and a heavily doped semiconductor region laterally abutted against the lightly doped semiconductor region; wherein one DRAM cell includes an access transistor and a storage capacitor, the access transistor comprises a third source region, a third drain region, and a third gate region, and the third source region or the third drain region includes a lightly doped semiconductor region and a heavily doped semiconductor region vertically abutted against the lightly doped semiconductor region.

According to one aspect of the invention, one edge of the first gate region is aligned or substantially aligned with an edge of the first source region, and another edge of the first gate region is aligned or substantially aligned with an edge of the first drain region.

According to one object of the invention, the complementary MOSFET structure further comprising a localized isolation region between the planar P type MOSFET and the planar N type MOSFET, and a highly doped P+ region in the first source region or the first drain region is shielded from the semiconductor substrate by the localized isolation region.

According to one aspect of the invention, the localized isolation region includes a vertically extended isolation region and a horizontally extended isolation region, and a latch-up path between the planar P type MOSFET and the planar N type MOSFET is at least dependent on a bottom length of the horizontally extended isolation region.

According to another object of the invention, a DRAM circuit according to the present invention comprises a semiconductor substrate with a semiconductor surface, an array core circuit with a sense amplifier circuit and a plurality of DRAM cells electrically coupled to the sense amplifier circuit, and a peripheral circuit electrically coupled to the array core circuit. Each DRAM cell includes an access transistor and a storage capacitor. Either the sense amplifier circuit or the peripheral circuit has a complementary MOSFET structure, the complementary MOSFET structure comprises a planar P type MOSFET comprising a first source region, a first drain region and a first gate region over the semiconductor surface, a planar N type MOSFET comprising a second source region, a second drain region and a second gate region over the semiconductor surface. Wherein the access transistor comprises a third source region, a third drain region, and a third gate region, at least portion of the third gate region is under the semiconductor surface; and the first source region and the first drain region are with a first lattice structure, and the third source region and the third drain region are with a second lattice structure, and the first lattice structure is different form the second lattice structure. Furthermore, the first source region or the first drain region includes a bottom surface lower than a bottom surface of the first gate region, and the third source region or the third drain region includes a bottom surface higher than a bottom surface of the third gate region.

According to one aspect of the invention, the third source region or the third drain region includes the bottom surface aligned or substantially aligned with a top surface of the third gate region.

According to one aspect of the invention, the first source region and the first drain region are independent from the semiconductor substrate, and the third source region and the third drain region are independent from the semiconductor substrate.

According to one aspect of the invention, wherein the semiconductor substrate is a silicon substrate, the first source region and the first drain region are selectively grown and laterally extended from a (110) orientation surface of the silicon substrate, and the third source region and the third drain region are selectively grown and vertically extended from a (100) orientation surface of the silicon substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a diagram illustrating circuit diagram of a DRAM chip.

FIG. 1B is a diagram illustrating a cross section of a traditional CMOS structure.

FIG. 1C is a diagram illustrating the parasitic Metal-Gated-Diode formed in the Gate-to-Source/Drain regions of the MOSFET and the GIDL issue in MOSFET.

FIG. 2A and FIG. 2B is a diagram illustrating a top view and a cross-section view along a cut line (X-axis) after the pad-nitride layer is deposited and the STI is formed.

FIG. 3A and FIG. 3B is a diagram illustrating a top view and a cross-section view along a cut line (X-axis) after the gate length is defined.

FIG. 3-1A and FIG. 3-1B is a diagram of another embodiment illustrating a top view and a cross-section view along a cut line (X-axis) after a shallow trench for channel region is formed.

FIG. 3-2A and FIG. 3-2B is a diagram of another embodiment illustrating a top view and a cross-section view along a cut line (X-axis) after channel region is selectively formed.

FIG. 3-3A and FIG. 3-3B is a diagram of another embodiment illustrating a top view and a cross-section view along a cut line (X-axis) after a shallow trench with rounded shape for channel region is formed.

FIG. 3-4A and FIG. 3-4B is a diagram of another embodiment illustrating a top view and a cross-section view along a cut line (X-axis) after channel region is selectively formed in the shallow trench with rounded shape.

FIG. 4A and FIG. 4B is a diagram illustrating a top view and a cross-section view along a cut line (X-axis) after the gate conductive region is formed.

FIG. 5A and FIG. 5B is a diagram illustrating a top view and a cross-section view along a cut line (X-axis) after the gate cap region is formed.

FIG. 6A and FIG. 6B is a diagram illustrating a top view and a cross-section view along a cut line (X-axis) after the pad nitride and the pad oxide outside the gate region are removed.

FIG. 7A and FIG. 7B is a diagram illustrating a top view and a cross-section view along a cut line (X-axis) after the spacers over the sidewalls of the gate region are formed.

FIG. 8A and FIG. 8B is a diagram illustrating a top view and a cross-section view along a cut line (X-axis) after the concaves outside the gate region are formed.

FIG. 9A and FIG. 9B is a diagram illustrating a top view and a cross-section view along a cut line (X-axis) after the localized isolation layers in the concaves are formed.

FIG. 10A and FIG. 10B are diagrams illustrating a top view and a cross-section view along a cut line (X-axis) after the semiconductor regions are grown laterally from exposed silicon sidewalls in the concaves.

FIG. 10C is a diagram of another embodiment illustrating a top view and a cross-section view along a cut line (X-axis) after the semiconductor regions are grown laterally from exposed silicon sidewalls in the concaves.

FIG. 10-1A and FIG. 10-1B are diagrams illustrating a top view and a cross-section view along a cut line (X-axis) after the semiconductor regions are grown laterally from exposed silicon sidewalls in the concaves according to another embodiment.

FIG. 11A and FIG. 11B is a diagram illustrating a top view and a cross-section view along a vertical dash cut line in one embodiment of planar CMOS structure in the peripheral circuit/sense amplifiers of the DARMchip according to the present invention.

FIG. 12 is a diagram illustrating of a traditional CMOS structure with the n+ and p+ regions not fully isolated by insulators.

FIG. 13A and FIG. 13B is a diagram illustrating a top view and a cross-section view along a horizontal dash cut line in another embodiment of planar CMOS structure in the peripheral circuit/sense amplifiers of the DARMchip according to the present invention.

FIG. 14 is a diagram illustrating the possible Latch-up path from the n+/p junction through the p-well/n-well junction to the n/p+ junction structure of a transitional CMOS structure.

FIG. 15A is a cross-section view of the proposed access transistors in the array core circuit of the DARM chip according to the present invention.

FIG. 15B is a cross-section view of the proposed access transistors in the array core circuit of the DARM chip after the concaves for accommodating the source/drain regions are formed.

FIGS. 16˜18 are cross-section views of formation steps regarding the proposed semiconductor gate of the NMOS transistor.

FIGS. 19˜21 are cross-section views of formation steps regarding the proposed semiconductor gate the PMOS transistor.

FIG. 22A is the cross-section view of the conventional poly gate transistor, and FIG. 22B is the cross-section view of the proposed semiconductor gate transistor according the present invention.

### DETAILED DESCRIPTION

This invention discloses a planar transistor and planar CMOSFET structure, especially used in the peripheral circuit of DRAM chip and in sense amplifiers of array core circuit of DRAM chip. The manufacturing method of the proposed planar NMOS and PMOS transistors is exemplarily illustrated as follows:
Step 10: Start.
Step 20: Based on the semiconductor substrate, define active regions for the NMOS and PMOS transistors and form deep shallow trench isolation (STI) structures.
Step 30: Form the gate structure above the original semiconductor surface of the semiconductor substrate.
Step 40: Form spacers covering the gate structure, and form concaves in the semiconductor substrate.
Step 50: Form localized isolation layers in the concaves.
Step 60: Expose sidewalls of silicon in the concaves, and Grow semiconductor regions laterally from exposed silicon sidewalls in the concaves to form the source region and drain region of the planar NMOS and PMOS transistors.

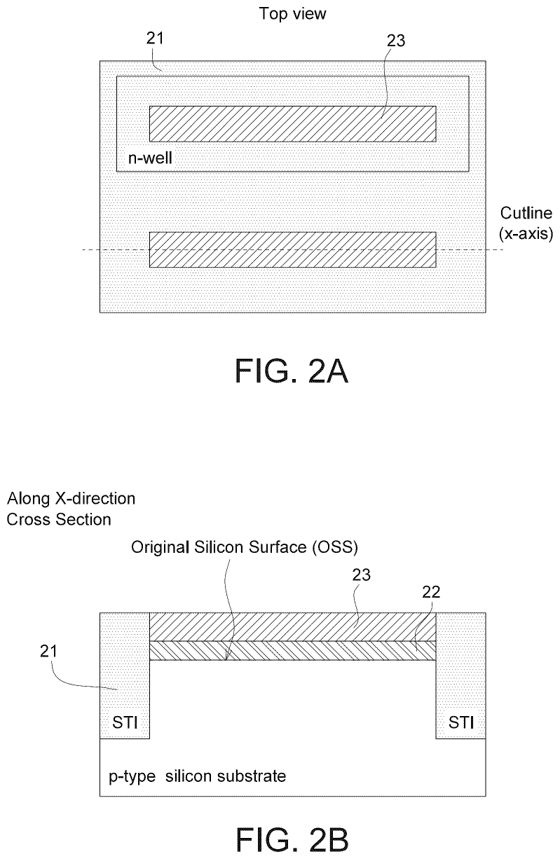

Please refer to FIG. 2A and FIG. 2B, Step 20 could include:
Step 202: A pad-oxide layer 22 is formed and a pad-nitride layer 23 is deposited.
Step 204: Use patterned photo-resistance (PR) to define the active regions of the planar NMOS and planar PMOS transistor, and remove parts of silicon material in the semiconductor substrate outside those active region patterns to create temporary trenches.
Step 206: Deposit oxide layer in the created temporary trenches, then etch back and planarize the oxide layer to form Shallow Trench Isolation (STI) 21, wherein the top surface of the STI 21 is aligned with the top surface of the pad-nitride layer 23, as shown in FIG. 2B which is the cross section view along the x-axis cutline in FIG. 2A.

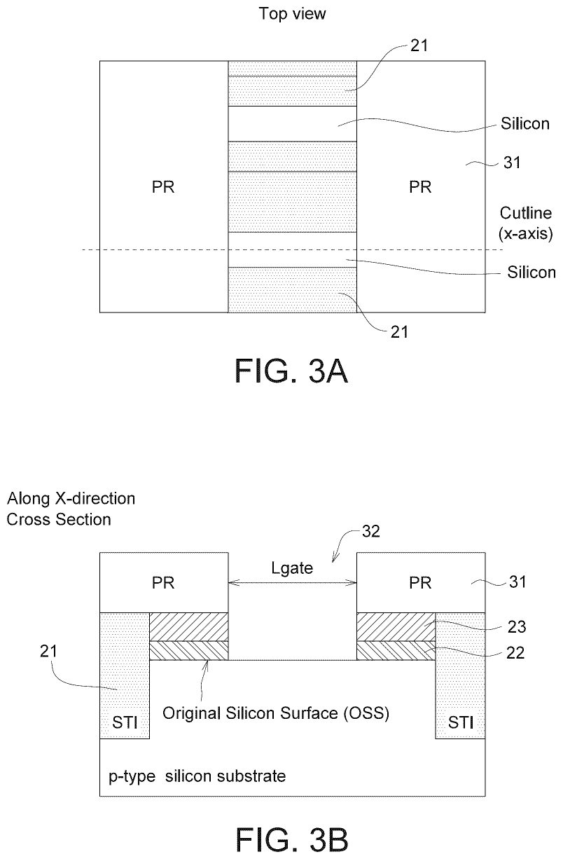

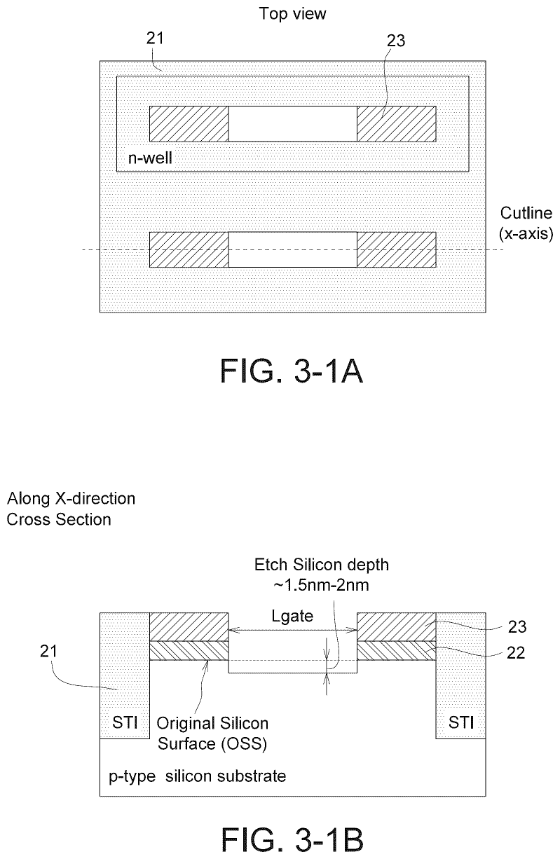

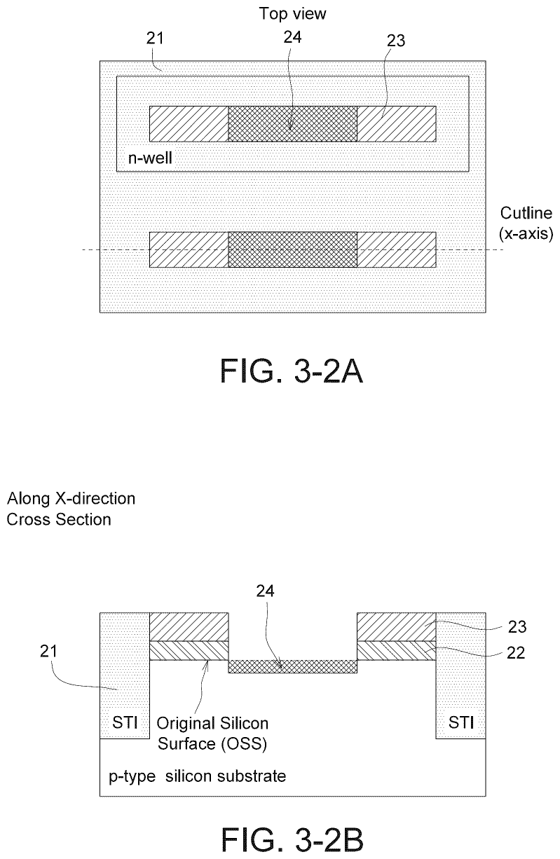

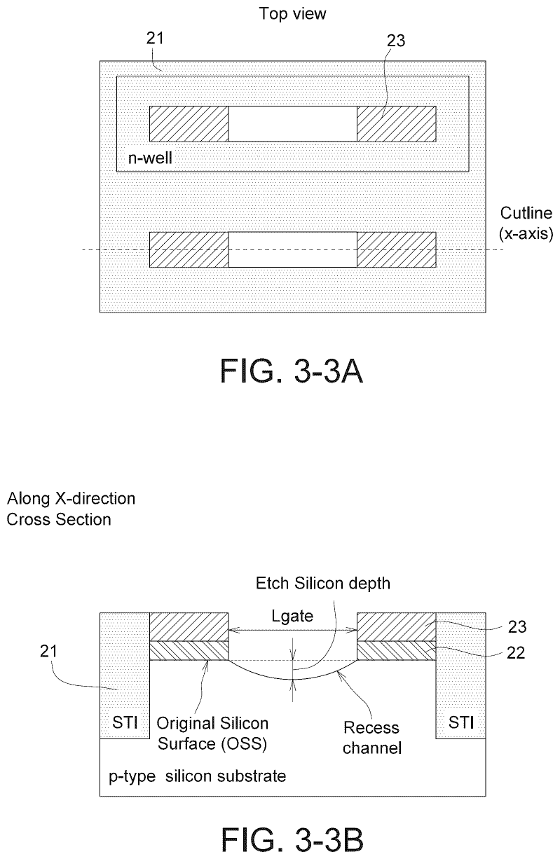

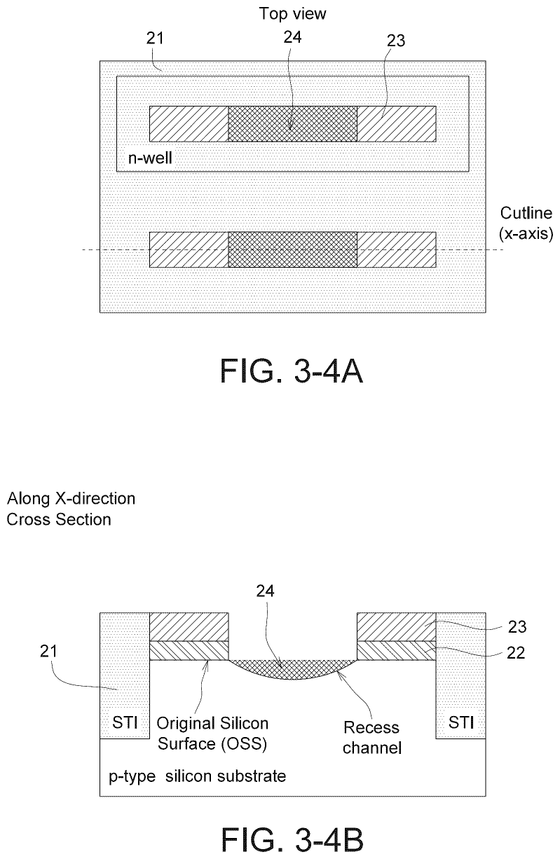

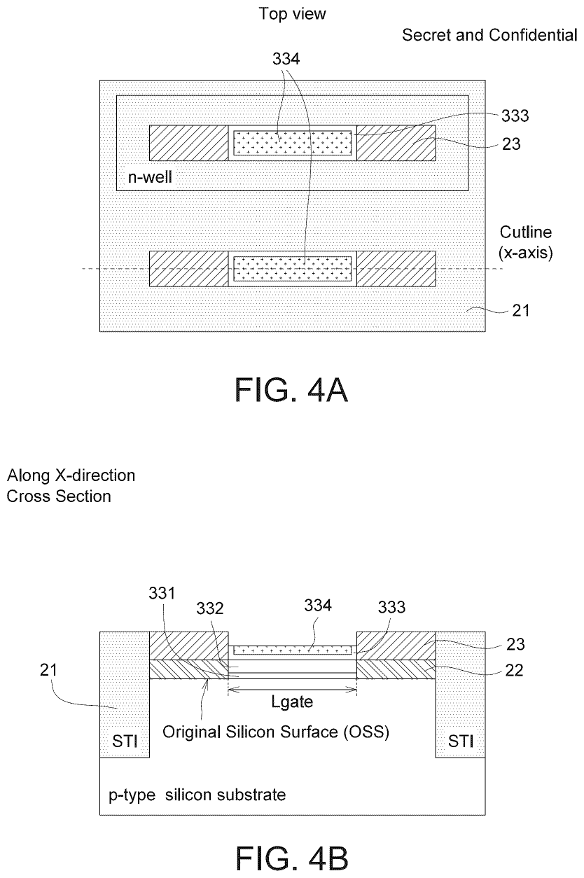

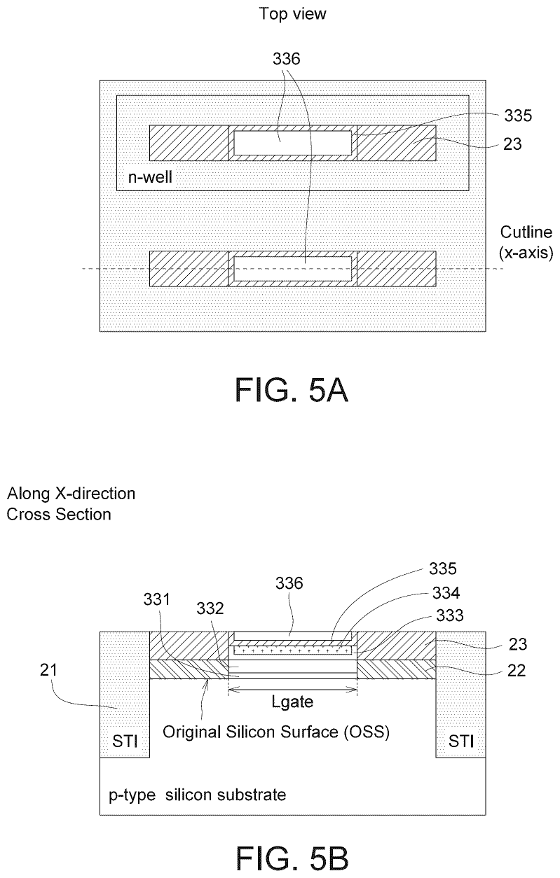

Please refer to FIGS. 3-5, Step 30 of forming the gate structure could include:
Step 302: Use another patterned photo-resistance (PR) to define the gate length (Lgate) of the gate regions for the planar NMOS and PMOS transistors, and then portion of the pad-oxide layer 302 and the pad-nitride layer 304 not covered by the PR are removed to form the gate accommodating trench 32, as shown in FIG. 3A and FIG. 3B, wherein FIG. 3B which is the cross section view along the x-axis cutline in FIG. 3A.
Step 304: subsequently form the gate dielectric layer 331 (such as thermal oxide or Hi-K material), highly doped polysilicon 332 (N+ polysilicon for MOS and P+ polysilicon for MOS), Ti/TiN layer 333, and Tungsten layer 334 in the gate accommodating trench 32, as shown in FIG. 4A and FIG. 4B, wherein FIG. 4B which is the cross section view along the x-axis cutline in FIG. 4A.
Step 306: Form a nitride cap layer 335 and an oxide cap 336 over the Tungsten layer 334 to complete the gate regions or gate structures of the NMOS and PMOS transistors, as shown in FIG. 5A and FIG. 5B, wherein FIG. 5B which is the cross section view along the x-axis cutline in FIG. 5A.

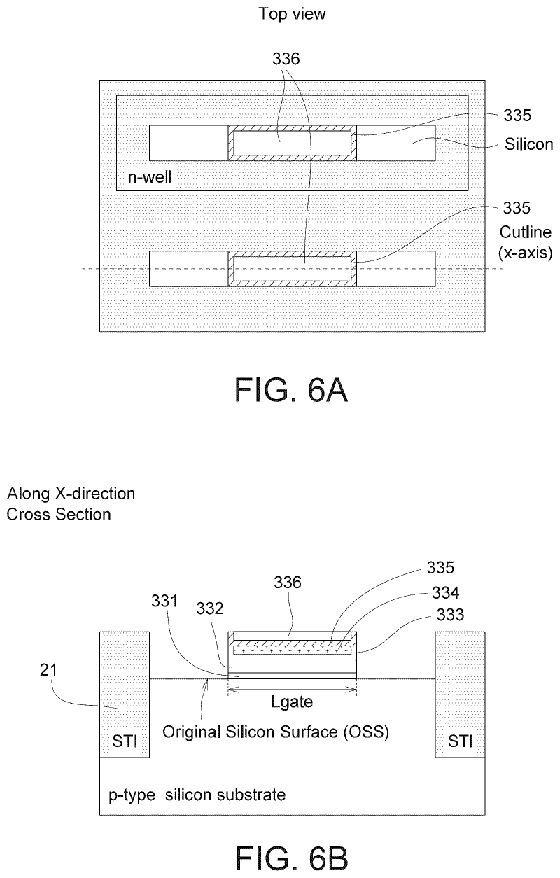

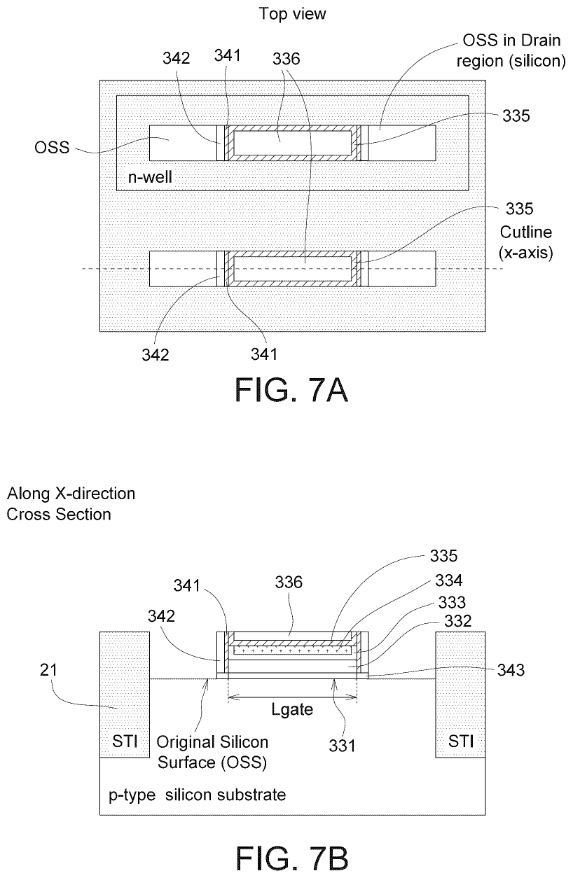

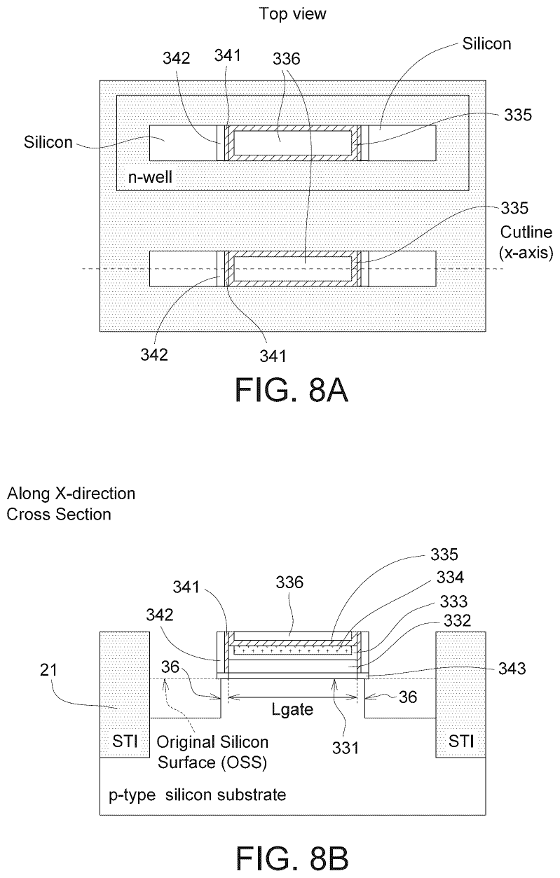

Then please refer to FIGS. 6-8, Step 40 could include:
Step 402: remove the pad-oxide layer 22 and the pad-nitride layer 23 between the STI layer 21 and the aforesaid gate regions to reveal the OSS of the substrate, as shown in FIG. 6A and FIG. 6B, wherein FIG. 6B which is the cross section view along the x-axis cutline in FIG. 6A.
Step 404: form the spacer layer on the sides of the aforesaid gate regions, wherein the spacer layer may include a thin oxide sublayer 343 thermally grown on the OSS of the substrate, a thin nitride sublayer 341 and a thin oxide sublayer 342 over thin oxide sublayer 343, as shown in FIG. 7A and FIG. 7B, wherein FIG. 7B which is the cross section view along the x-axis cutline in FIG. 7A.
Step 406: Etch portion of the semiconductor substrate to form concaves in the semiconductor substrate, as shown in FIG. 8A and FIG. 8B, wherein FIG. 8B which is the cross section view along the x-axis cutline in FIG. 8A. Each concave includes an exposed vertical side-surface 36 with (100) orientation right under the spacer layer in step 404, when the semiconductor substrate is a silicon substrate.

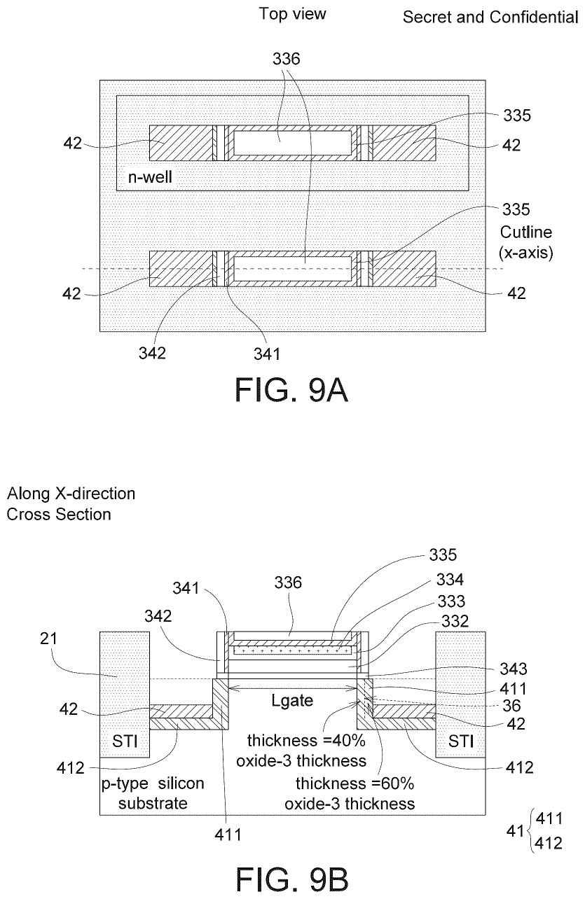

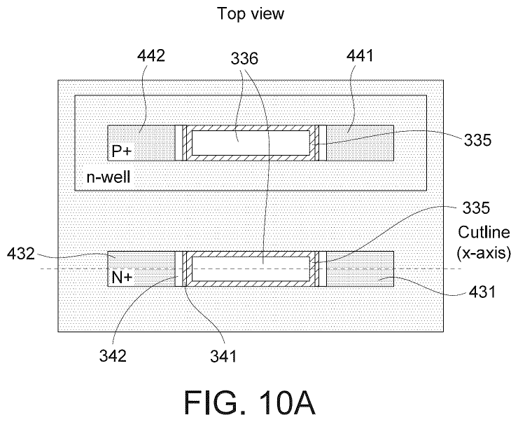

please refer to FIG. 9A and FIG. 9B, Step 50 could include: thermally grow an oxide-3 layer 41 which includes a vertical oxide-3V layer 411 covering the sidewalls of the aforesaid concaves and a horizontal oxide-3B layer 412 covering the bottoms of the aforesaid concaves in step 406. Afterward, deposit Nitride-3 material with sufficient thickness to fully fill up the aforesaid concaves and then use an etch back process to remove the unnecessary portion of the Nitride-3 material to leave only a suitable Nitride-3 layer 42 inside the aforesaid concaves, as shown in FIG. 9A and FIG. 9B, wherein FIG. 9B which is the cross section view along the x-axis cutline in FIG. 9A. It is mentioned that the Nitride-3 layer 42 could be replaced by any suitable insulation materials.

To be mentioned, the thickness of the Oxide-3V layer 411 and the Oxide-3B layer 412 drawn in FIG. 9B and following figures are only shown for illustration purpose, but it is very important to design this thermally grown oxide-3 layer 41 such that the thickness of Oxide-3V layer 411 be very accurately controlled under both precisely controlled thermal oxidation temperature, timing and growth rate. The thermal oxidation over a well-defined silicon surface should result in that 40% of the thickness in Oxide-3V layer 411 takes away portion of silicon substrate from the aforesaid exposed (110) vertical side-surface 36, and the remaining 60% of the thickness of Oxide-3V layer 411 be counted as an addition outside the aforesaid exposed (110) vertical side-surface 36 (such a distribution of 40% and 60% on Oxide-3V layer 411 is particularly drawn clearly in FIG. 9B). Since the thickness of Oxide-3V layer 411 is very accurately controlled based on the thermal oxidation process, the edge of the Oxide-3V layer 411 could be aligned with the edge of the gate region. Of course, depending on the etching condition and thermal oxide growth condition, in another embodiment, part of Oxide-3V layer 411 (such as less than 5˜10%) could be underneath the gate structure.

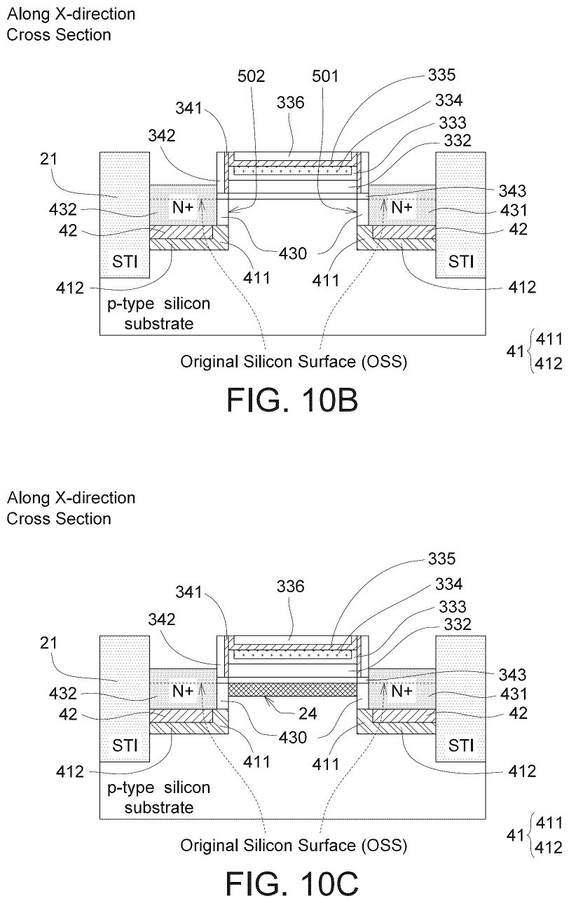

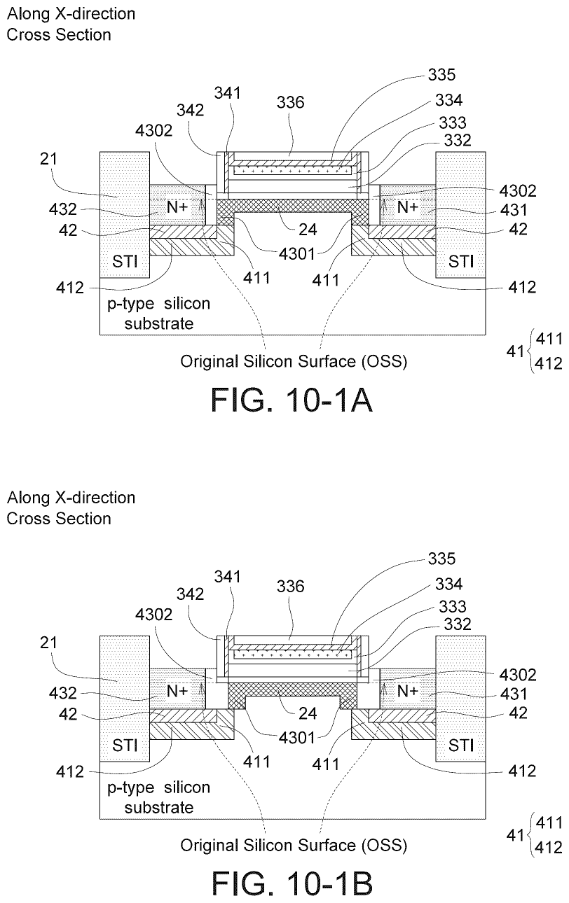

Please refer to FIG. 10A and FIG. 10B, Step 60 could include:
Step 602: portion of the Oxide-3V layer 411 above the Nitride-3 layer 42 are removed to expose anther vertical semiconductor sidewalls 501 and 502, again, those vertical semiconductor sidewalls 501 and 502 have (110) crystal orientation, when the semiconductor substrate is the silicon substrate. The remaining Oxide-3 layer 41 and the Nitride-3 layer 42 could be named as Localized Isolation into Silicon Substrate (“LISS”).
Step 604: Grow the first semiconductor regions 430 laterally from the exposed vertical semiconductor sidewalls 501 and 502, respectively. Each of the first semiconductor regions 430 could include a lightly doped region (or a Lightly Doped Drain, “LDD”), or include an undoped region plus a lightly doped region. The first semiconductor region 430 could be formed by selectively grown method, such as Selective Epitaxial Growth (SEG) technique or Atomic Layer Deposition (ALD) technique.
Step 606: Grow the second semiconductor regions laterally from those first semiconductor regions 430; each of the second semiconductor regions includes a highly doped region which could be formed by selectively grown method as well. Thus, the drain region of the planar NMOS transistor includes an N− LDD region and an N+ doped region 431, and the source region of the planar NMOS transistor includes another N-LDD region and an N+ doped region 432. Similarly, the drain region of the planar PMOS transistor includes a P− LDD region and a P+ doped region 441, and the source region of the PMOS transistor includes another P− LDD region and a P+ doped region 442.

It is noted that each of the exposed vertical semiconductor sidewalls 501 and 502 has its vertical boundary aligned (or substantially aligned) with the edge of the gate region, as shown in FIG. 10B. That is, the edge of the source or drain region in the planar transistor is aligned (or substantially aligned) with the edge of the gate region, and the present invention provides a profound SAPC (Alignment from Gate-to-Source/Drain and Precisely Created Crystalline Structure for Forming Source/Drain) Technology. Thus, the alignment from the Edge of Source/Drain to the Edge of the gate region can thus be precisely defined or controlled by using thermal oxidation and crystalline structure, and the GIDL effect should be reduced in contrast to the conventional way of using LDD implantation to serve as the alignment of Gate-edge to LDD.

Furthermore, the new source/drain regions are formed by all (110) crystalline silicon; improving the conventional way of growing source/drain regions from two different seeding regions as explained causes lattice mixtures of (100) orientation and (110) orientation in silicon substrate. So the present invention could create better Source/Drain-to-Channel conduction mechanism, and the sub-threshold leakage could be reduced as well. Moreover, the effective channel length (Leff) between the source region and the drain region could be almost equal to the gate length (“Lgate” shown in FIG. 10B) during the formation of the planar transistors, because no ion implantation and thermal annealing are required. Since there is no need to use ion-implantation to form LDD region or the source/drain regions, there is no need to use thermal annealing process to reduce defects. Therefore, as no extra defects are generated once which were induced and hard to totally eliminate even by annealing process any unexpected leakage current sources should be significantly minimized.

Additionally, even there is another thermal annealing process to reduce the connecting resistance between the capacitor and the access transistor, since the first semiconductor regions 430 of the present invention could include an undoped region plus a lightly doped region, the dopant redistribution due to the another thermal annealing process will not significantly reduce the effective channel length (Leff), therefore, the design rule for the reserved gate length (“Lgate”) of the gate region according to the present invention would be reduced, as compared with that of the conventional CMOS structure. Using technology node (Lamda or λ) of 20˜30 nm for planar transistor as an example, the reserved gate length in the present invention would be between 1.5λ˜3λ, such as 2λ or 2.5λ.

Meanwhile, each of the source and drain region of the planar transistors according to the present invention is isolated by insulation materials (the Nitride-3 layer 42 and the remaining oxide-3 layer 41) on the bottom structure, and isolated by STI layer 21 along three sidewalls, the junction leakage possibility can only happen to very small areas of the first semiconductor region 430 to channel region (right under the gate region of the planar transistor) and thus be significantly reduced.

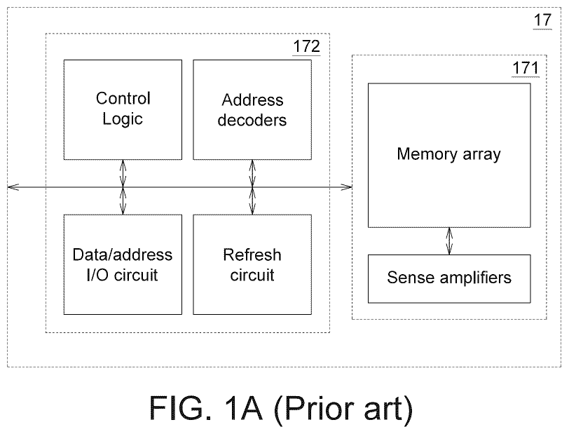

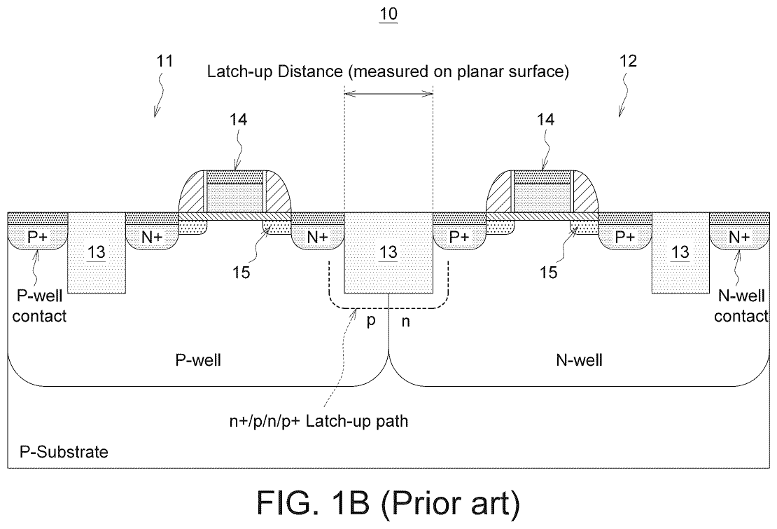

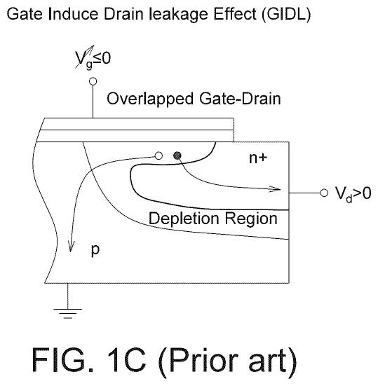

In the previous embodiment, a channel region could be formed underneath and close to the Original Silicon Surface (OSS) through ion-implantation (not shown) before the formation of the gate structure. However, besides the channel region formed by ion-implantation, a channel region according to the present invention could be formed by selective growth. For example, before forming the gate dielectric layer 331 in FIG. 4B, the revealed silicon surface could be etched to form a shallow trench with a depth of 1.5 nm˜3 nm, as shown in FIG. 3-1A and FIG. 3-1B. Then, a channel region 24 is selectively grown in the shallow trench, as shown in FIG. 3-2A and FIG. 3-2B. Thereafter, the processes to form the gate region, the source region, and the drain region mentioned in FIG. 4A/FIG. 4B˜FIG. 10A/FIG. 10B could be similarly applied to form another planar transistor structure shown in FIG. 10C.

Still in another embodiment, before forming the gate dielectric layer 331 in FIG. 4B, the revealed silicon surface could be etched to form a shallow trench with a rounded or curved shape, as shown in FIG. 3-3A and FIG. 3-3B. Then, a semiconductor channel region 24 is selectively grown along the sidewall of the shallow trench, as shown in FIG. 3-4A and FIG. 3-4B. Since the semiconductor channel region 24 is selectively grown along the sidewall of the shallow trench which is a curved or rounded shape, the channel length in this embodiment could be longer. Thereafter, the processes to form the gate region, the source region, and the drain region mentioned in FIG. 4A/FIG. 4B˜FIG. 10A/FIG. 10B could be similarly applied to form another planar transistor.

FIG. 10-1A and FIG. 10-1B are diagrams illustrating a top view and a cross-section view along a cut line (X-axis) after the semiconductor regions are grown laterally from exposed silicon sidewalls in the concaves according to another embodiment. The difference between FIG. 10-1A/FIG. 10-1B and FIG. 10C is that, before growth of the LDD region 4302 for NMOS, a vertical P-type layer 4301 is first formed by selective growth, and then the LDD region 4302 and the heavily doped regions 431/432 are sequentially formed by selective growth. Such vertical P-type layer 4301 could reduce the leakage current during the OFF state of the NMOS transistor.

In another embodiment, the source (or drain) region could further comprise some Tungsten or other suitable metal materials (not shown) in the concaves and contacting the heavily doped region of source (or drain) region which is selectively grown. Thus, the source (or drain) region is a composite source (or drain) region. Thus, the external metal contact will be connected to the metal region of the composite source (or drain) region, and such Metal-to-Metal contact has much lower resistance than the traditional Silicon-to-Metal contact.

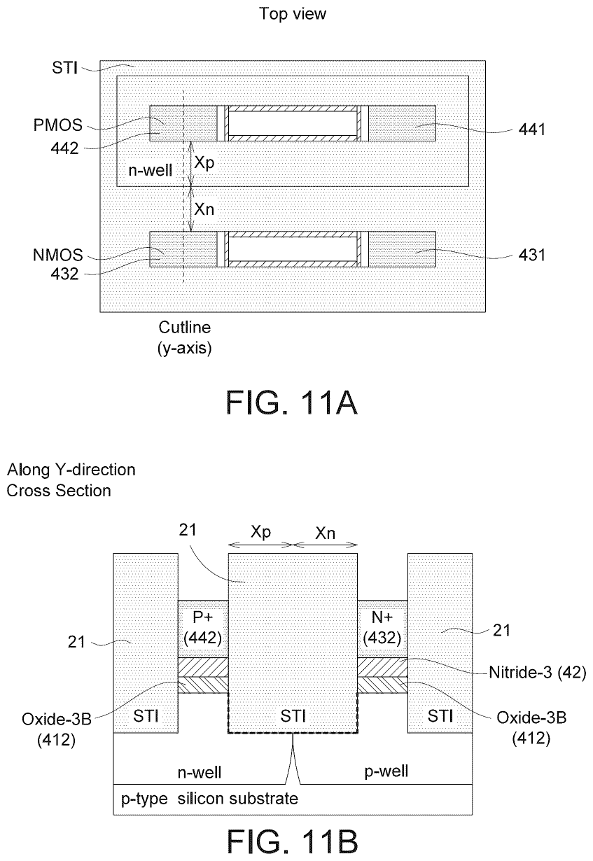

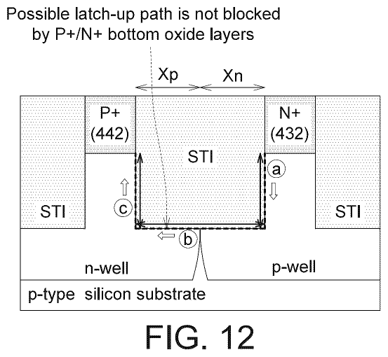

Furthermore, as shown in FIGS. 11A˜11B. FIG. 11A is a top view of the new planar CMOS structure according to the present invention, and FIG. 11B is a diagram illustrating a cross section of the new planar CMOS structure along the cutline (Y-axis) in FIG. 11A. The planar PMOS and planar NMOS transistors in FIGS. 11A˜11B are vertically positioned side-by-side. In FIG. 11A, the four sides of the new planar CMOS structure is surrounded by the STI 21. Moreover, as shown in FIG. 11B, there exists the composite localized isolation (including the oxide-3 layer 412 and the nitride-3 payer 42) between the P+ source region 442 (or P+ drain region 441) of the PMOS and the n-type N-well, so is another composite localized isolation (including the oxide-3B layer 412 and the nitride-3 layer 42) between the N+source region 432 (or N+ drain region 431) of the NMOS and the p-type P-well or substrate. That is, each of drain region and source region of new planar CMOS structure is surrounded by the STI 21 on three sidewalls and by the composite localized isolation on the bottom wall. Thus, the possible latch-up path from the bottom of the P+ region of the PMOS to the bottom of the N+ region of the NMOS is fully blocked by localized isolations. Therefore, latch-up distance Xp+Xn (measured on planar surface) could be shrunk as small as possible without incurring serious latch-up issue. On the other hand, in the traditional CMOS structure the n+ and p+ regions are not fully isolated by insulators as shown in FIG. 1B or FIG. 12, the possible Latch-up path exists from the n+/p junction through the p-well/n-well junction to the n/p+junction includes the length a, the length b, and the length c.

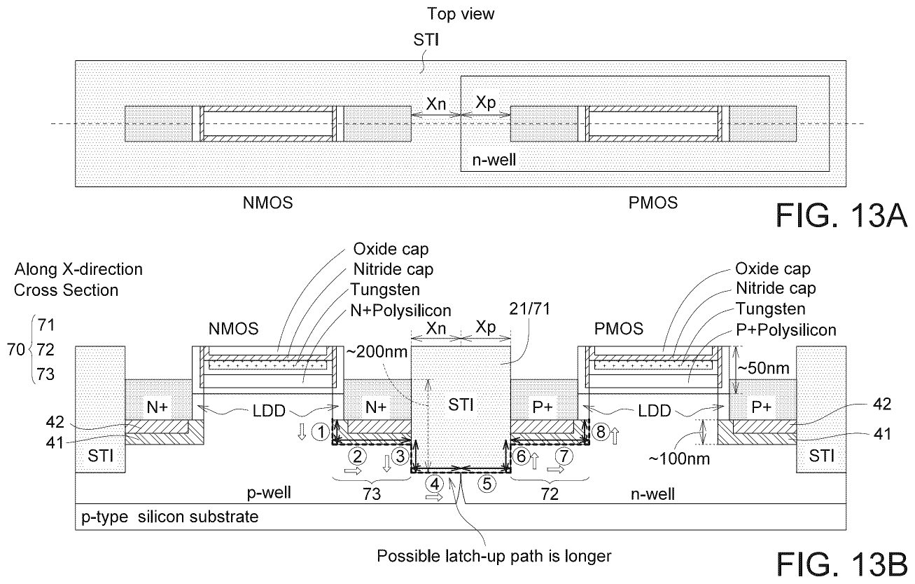

Furthermore, please refer to FIGS. 13A˜13B according to another embodiment of the present invention. FIG. 13A is a top view of the new planar CMOS structure with a planar NMOS transistor and a planar PMOS transistor, FIG. 13B is a diagram illustrating a cross section of the new CMOS structure along the horizontal dash cutline in FIG. 13A. The planar PMOS and planar NMOS transistors in FIGS. 13A˜13B are laterally positioned side-by-side. As shown in FIG. 13B, it could be simplified that there is a cross-shape LISS 70 between the PMOS transistor and NMOS transistor. The cross-shape LISS 70 includes a vertically extended isolation region 71 (such as the STI 21, the vertical depth under the OSS as shown in FIG. 13B would be around 150˜300 nm, such as 200 nm), a first horizontally extended isolation region 72 (the vertical depth would be around 50 nm˜120 nm, such 100 nm) on the right hand side of the vertically extended isolation region 71, and a second horizontally extended isolation region 73 (the vertical length depth would be around 50 nm˜120 nm, such 100 nm) on the left hand side of the vertically extended isolation region 71.

Each of the horizontally extended isolation regions could include the oxide-3 layer 41 and the nitride-3 layer 42. The vertical depth of the source/drain region of the PMOS/NMOS transistor is around 30˜50 nm, such as 40 nm. The vertical depth of the gate region of the PMOS/NMOS transistor is around 40˜60 nm, such as 50 nm shown in FIG. 13B.

In this embodiment, the first and second horizontally extended isolation regions 72/73 are not right underneath the gate structure or the channel of the transistor. The first horizontally extended isolation region 72 (right hand side of the vertically extended isolation region 71) contacts to a bottom side of the source/drain region of the PMOS transistor, and the second horizontally extended isolation region 73 (left hand side of the vertically extended isolation region 71) contacts to a bottom side of the source/drain region of the MMOS transistor. Therefore, the bottom sides of the source/drain regions in the PMOS and NMOS transistors are shield from the semiconductor substrate. Moreover, the first or second horizontally extended isolation region 72/73m be composite isolation which could include two or more different isolation materials (such as the oxide-3 41 and the Nitride-3 42), or include two or more same isolation materials but each isolation material is formed by separate process.

As described before in the text and FIG. 1B, a drawback of conventional CMOS configuration/ technology in contrast to pure-NMOS technology is that once a parasitic bipolar structure such as n+/p-sub/n-well/p+ junctions does exist and unfortunately some bad design cannot resist big current surges due to noises to trigger Latch-up to cause entire chip operation shutdown or permanent damages to chip functionality. The layout and process-rule for conventional CMOS always need to very large space to separate n+ source/drain regions of NMOS from the p+ source/drain regions of PMOS, called as Latch-up Distance (FIG. 1B) which consumes a lot of planar surfaces to inhibit any possibility of Latch-up. Moreover, if the source/drain n+/p and p+/n semiconductor junction area are too large, once the forward biasing accident is induced, the large surging current can be triggered to cause Latch-up.

The new planar CMOS structure in FIG. 13B results in a much longer path from the n+/p junction through the p-well (or p-substrate)/n-well junction to the n/p+ junction. As shown in FIG. 7C, according to the present invention, the possible Latch-up path from the LDD-n/p junction through the p-well /n-well junction to the n/LDD-p junction includes the length \textcircled{1}, the length \textcircled{2} (the length of the bottom wall of one horizontally extended isolation region), the length \textcircled{3}, the length \textcircled{4}, the length \textcircled{5}, the length \textcircled{6}, the length \textcircled{7} (the length of the bottom wall of another horizontally extended isolation region), and the length \textcircled{8} marked in FIG. 13B.

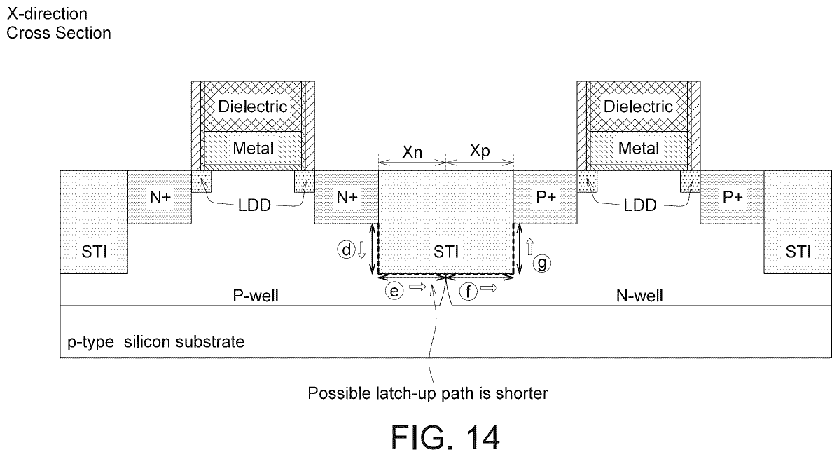

On the other hand, in traditional CMOS structure, the possible Latch-up path from the n+/p junction through the p-well/n-well junction to the n/p+ junction just includes the length d , the length e, the length f, and the length g (as shown in FIG. 14). Such possible Latch-up path of FIG. 13B is longer than that in FIG. 14. Therefore, from device layout point of view, the reserved edge distance (Xₙ+Xₚ) between NMOS and PMOS in FIG. 13B according to the present invention could be smaller than that in FIG. 14. Moreover, in FIG. 13B, the potential Latch-up path begins from LDD-n/p junction to the n/LDD-p junction, rather than n+/p junction to the n/p+ junction in FIG. 14. Since the doping concentration in LDD-n or LDD-p region of FIG. 13B is lower than the doping concentration in n+ or p+ region of FIG. 14, the quantity of electrons or holes emitted from LDD-n or LDD-p region in FIG. 13B would be much lower than that emitted from n+ or p+ region in FIG. 14. Such lower emission of carriers will not only effectively decrease the possibility of induced Latch-up phenomenon, but also dramatically reduce the current even the Latch-up phenomenon is induced. Since both n+/p and p+/n junction areas are significantly reduced, even some abrupt forward-biasing of these junctions can reduce the abnormal current magnitude to deduct the chance of forming Latch-up in FIG. 13B.

Referring to FIG. 13B again, according to the present invention, the source or drain region of the planar PMOS is surrounded by the first horizontally extended isolation region 72 and the vertically extended isolation region 71, only the LDD region (the vertical length would be around 10˜50 nm) of the source or drain region of the planar PMOS contacts to the semiconductor substrate to form a LDD-p/n junction, rather than p+/n junction. Similarly, the source or drain region of the planar MMOS is surrounded by the second horizontally extended isolation region 73 and the vertically extended isolation region 71, and only the LDD region (the vertical length would be around 40 nm) of the source or drain region of the planar NMOS contacts to the substrate to form a LDD-n/p junction, rather than p+/n junction. Therefore, the n+ regions of the planar NMOS and the p+ regions of the planar PMOS are shielded from the substrate or well region. Moreover, since the first or second horizontally extended isolation region 72/73 is composite isolation and thick enough, the parasitic Metal-Gated-Diode induced between the source (or drain) region and the silicon substrate could be minimized. Additionally, the Gate Induce Drain leakage (GIDL) effect could be improved as well. It is expected that the planar Latch-up distance reserved for neighboring NMOS and PMOS transistors be significantly shortened such that the planar areas of the new planar CMOS can be largely reduced.

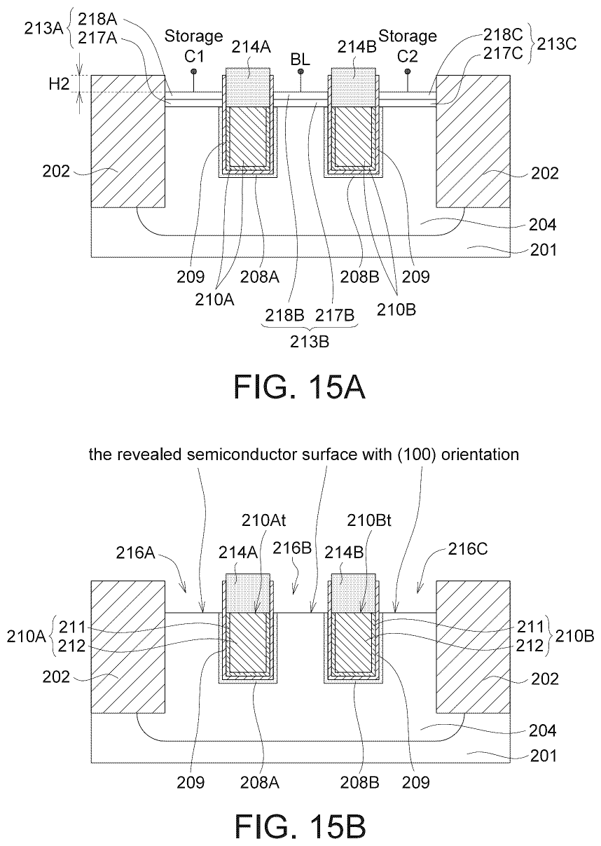

Additionally, such source/drain regions directly outgrown from a specific crystalline plane of the semiconductor substrate could be applied to the access transistors of the DRAM cells in the array core circuit of the DRAM chip, each DRAM cell includes an access transistor and a storage capacitor. As shown in FIG. 15A, the access transistor Q1 includes the source region 213A connected to a storage capacitor (C1), the drain region 213B connected to a bitline of the DRAM chip, the gate dielectric layer 209 (such as oxide), the gate conductive region 210A (including metal or polysilicon), the dielectric gate caps 214A (such as oxide/nitride), and the U-shape channel region 208A surrounding the gate conductive region 210A. Another access transistor Q2 includes the source region 213C connected to a storage capacitor (C2), the drain region 213B connected to the bitline of the DRAM chip, the gate dielectric layer 209 (such as oxide), the gate conductive region 210B (including metal or polysilicon), the dielectric gate caps 214B (such as oxide/nitride), and the U-shape channel region 208B surrounding the gate conductive region 210B. The access transistor Q1 and the access transistor Q2 are U-groove transistors or buried gate transistors, and could be formed in the well area 204 of the substrate 201 and enclosed by the STI region 202.

It is mentioned that, the source region 213A, the drain region 213B, and the source region 213C could be selectively grown and vertically outgrown from the revealed silicon surface with (100) orientation in the first recess 216A, the second recess 216B and the third recess 216C as shown in FIG. 15B. The source region 213A may include the LDD region 217A and the heavy doped region 218A, the drain region 213B may include the LDD region 217B and the heavy doped region 218B, and the source region 213C may include the LDD region 217C and the heavy doped region 218C, as shown in FIG. 15A. The source/drain regions of the access transistor in the DRAM cell of the present invention are vertically outgrown (such as by Selective Epitaxial Growth technique or Atomic Layer Deposition technique) and directly from (100) crystalline planes, their interfaces are formed seamless with the channel region. Furthermore, there is no ion-implantation process during the formation of the source/drain regions and no thermal annealing process which can make junction boundaries hard to be defined and controlled.

To sum up, since the source/drain regions of planar transistors of the CMOS structure in peripheral circuit/sense amplifiers of DRAM chip are laterally outgrown and directly from (110) crystalline planes, their interfaces are formed seamless with the channel region so that the gate length (Lgate) is precisely controlled. Furthermore, the plane of LDD (Lightly Doped Drain) is outgrown horizontally from both transistor channel and substrate body with in-situ doping technique during the selective growth, there is no ion-implantation process which can only be formed from the top silicon downward into the source/drain regions and no thermal annealing process which can make junction boundaries hard to be defined and controlled. Unlike the conventional doped regions formed by ion-implantation process, such selectively grown semiconductor regions (such as undoped region, LDD region, and heavily doped region) are independent from the semiconductor substrate.

The present invention can more precisely define the boundary edge of source/drain to the edge of the gate region, and the effective channel length (Leff) can be well controlled for minimizing SCE, GIDL and junction leakage currents.

Furthermore, the n+ and p+ regions are fully isolated by insulators in this newly invented planar CMOS structure, and the proposed LISS would increase the isolation distance into silicon substrate to separate junctions in NMOS and PMOS transistors so that the surface distance between junctions can be decreased.

Moreover, in the present invention the SEG formation of LDD to heavily doped regions even including various non-silicon dopants such as Germanium or Carbon atoms to increase stresses to enhance channel mobility. The doping concentration profile is controllable or adjustable in the SEG/ALD formation of source/drain regions according to the present invention.

Furthermore, in well-known CMOS process, the conductive material for the gate of the transistor may be of polysilicon or metal, wherein polysilicon is used because its work function is compatible with the Si substrate, and is commonly used in the gate first process. Polysilicon is a material consisting of small silicon crystals. But the conductivity of the poly-silicon is very low, and because of this low conductivity, the charge accumulation is low, leading to a delay in channel formation and thus unwanted delays in circuits. Thus, the poly-silicon is usually doped with impurity to make it behave like a perfect conductor and reduce the delay.

However, in polysilicon gate CMOS process, the polysilicon gate is doped by ion implantation and issues arise when the polysilicon gate is not doped heavily enough or is not uniform doped. Thus, there are limitations to the dopant activation concentration, for example, in PMOS transistor such dopant activation concentration is usually less than 1×10²⁰/cm³ (such as 7×10¹⁹/cm³), and in NMOS transistor such dopant activation concentration is usually less than 4×10²⁰/cm³(such as 2.5×10²⁰/cm³). In addition, it will often cause polysilicon depletion effect which is the phenomenon in which unwanted variation of threshold voltage of the MOSFET devices using polysilicon as gate material is observed, leading to unpredicted behavior of the electronic circuit. Thus, a critical issue in advanced semiconductor processing for the poly silicon gate process is to have adequate dopant activation in the polycrystalline silicon (poly-Si) gate to minimize such polysilicon depletion effect.

On the other hand, metal is introduced for the gate conductive material at the time when SiO₂ dielectrics are being replaced by high-k dielectrics, such as Hafnium oxide, as gate oxide in the mainstream CMOS technology, especially for the gate last process. Since there is no polysilicon used in the gate structure, such high-k dielectric metal gates (HKMG) were introduced to solve the polysilicon depletion effect. Nevertheless, such HKMG process is complex and expensive as compared with the polysilicon gate CMOS process.

The present invention further solves the dopant activation concern in the conventional polysilicon gate transistor, and increases dopant activation concentration in semiconductor/silicon gate of the NMOS transistor not less than 3×10²⁰/cm³ (N+), such as 4×10²⁰ /cm³ (N+) or higher.

Furthermore, the dopant activation concentration in semiconductor/silicon gate of the PMOS transistor of the present invention could be enhanced not less than 8×10¹⁹/cm³ (P+), such as 1×10²⁰/cm³ (P+) or higher. Such high dopant activation concentration can reduce polysilicon depletion effect, reduce the thickness of the gate dielectric layer, and improve Ion (On current) and gate control capability.

In the conventional transistor with the polysilicon gate structure, the dopant activation concentration in such polysilicon gate is just around 2.5×10²⁰/cm³ for the conventional NMOS transistor, and around 7×10¹⁹/cm³ for the conventional PMOS transistor. During the manufacturing of the conventional polysilicon gate, usually a layer of undoped polysilicon is deposited over the gate oxide layer. Thereafter, using NMOS transistor as example, Arsenic (As) or Phosphor (P) ions are implanted into the undoped polysilicon and then rapid thermal annealing is used for activating the dopant concentration.

On the other hand, in the proposed transistor with the highly doped silicon gate structure, the dopant activation concentration in such highly doped silicon gate could be greater than 4×10²⁰/cm³for the NMOS transistor, and be greater than 1×10²⁰/cm³ for the PMOS transistor.

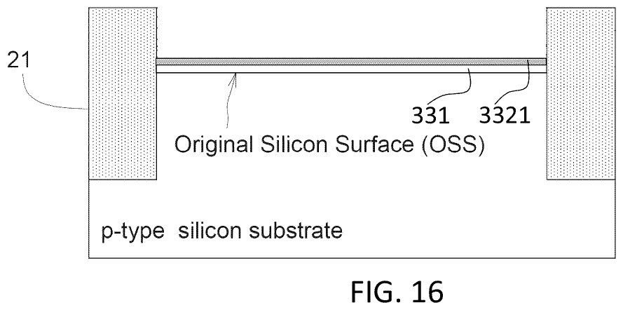

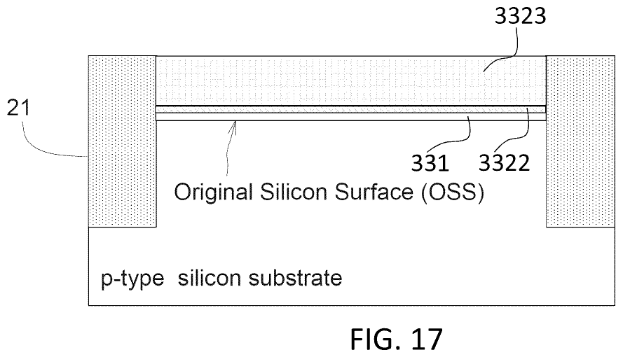

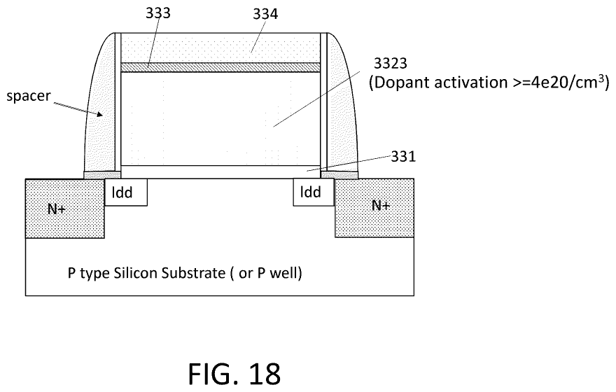

According to the present invention shown in FIGS. 16-18 which illustrate the exemplary manufacturing processes for the NMOS transistor, in order to increase the dopant activation concentration in the gate structure, after forming the gate dielectric layer 331 (such as thermal oxide or Hi-K material), a thin layer (such as 6˜10 nm) of undoped or doped amorphous silicon (or polysilicon) 3321 is first deposited at temperature of 500˜650° C. over the gate dielectric layer 331, as shown in FIG. 16. Then, such amorphous silicon layer is annealed at temperature around 1000° C. or higher (such as, laser annealing ˜1200 C plus thermal annealing ˜600 C) for recrystallization and turned into larger grains silicon layer, and the size of the grain could be more than 1˜2 um (see T. I. KAMINS AND T. R. CASS, “STRUCTURE OF CHEMICALLY DEPOSITED POLYCRYSTALLINE-SILICON FILMS”, Thin Solid Films, 16 (1973) 147-165; see also Yasuo Wada and Shigeru Nishimatsu, “Grain Growth Mechanism of Heavily Phosphorus-implanted Polycrystalline Silicon”, J. Electrochem. Soc.: SOLID-STATE SCIENCE AND TECHNOLOGY, Vol. 125, No. 9, 1499-1504, September 1978).

Thereafter, as shown in FIG. 17, using the larger grains silicon layer 3322 as the seed layer, selectively grow (such as selective epitaxy growth “SEG”) a layer of in-situ N+ doped silicon 3323 and then annealed by rapid thermal anneal (RTA) process at temperature around 1000° C. or higher, such that the dopant activation concentration in the selective grown Si layer could be around 4×10²⁰/cm³ (see Z.N. Weinrich, et al, “Dopant-defect interactions in highly doped epitaxial Si:P thin films”, Thin Solid Films 685 (2019) 1-7). Furthermore, since the thickness of the original undoped amorphous silicon layer is quite thin, through the aforesaid RTA the dopants in the in-situ N+ doped silicon layer will out-diffuse into the recrystallized larger grains silicon layer, such that the dopant concentration of the recrystallized larger grains silicon layer is almost the same as that of the in-situ N+doped silicon layer. Thus, after the rapid thermal anneal (RTA), it is almost difficult to differentiate with the layer of in-situ N+doped silicon 3323 and the larger grains silicon layer 3322.

Afterward, to complete a NMOS transistor structure, as shown in FIG. 18, standard gate patterning process could be applied to form the gate shape, TiN layer 333 and Tungsten layer 334 could be deposited over the in-situ doped N+ silicon 3322, LDD regions and the Nitride spacers could then be formed, and N+ source/drain regions could be formed by ion implantation and annealing processes, as shown in FIG. 18. It is noticed that the size of the grain in the recrystallized larger grains silicon layer could be more than 1˜2 um, so is the in-situ N+ doped silicon layer formed by SEG. After standard gate patterning process is formed based on technology node of 28 nm or lower, the gate length is usually not greater than 150 nm. Therefore, within the gate length of the in-situ N+ doped silicon layer, it is almost a single crystalline layer; or along a cutline of the gate length, it will include no more than three silicon grains.

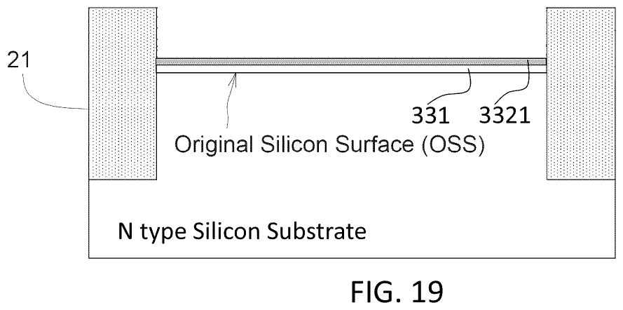

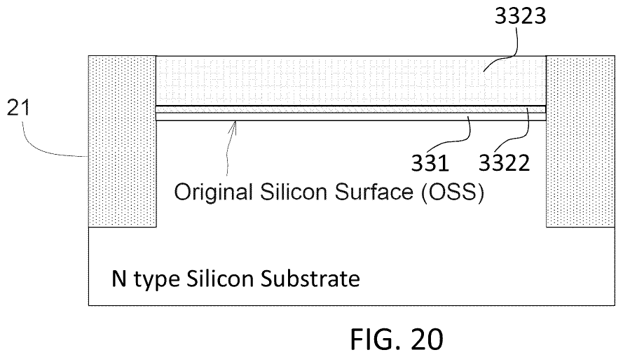

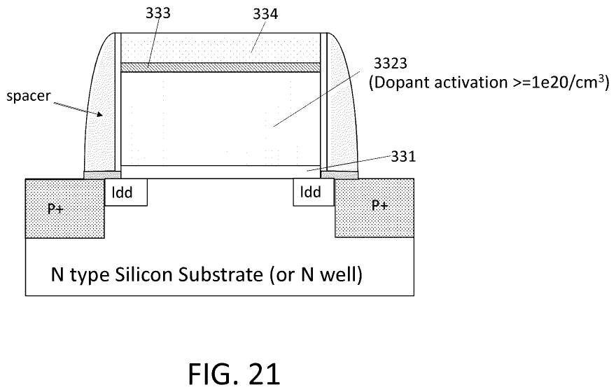

Similarly, in the processes forming conventional polysilicon gate of PMOS transistor, wherein a layer of undoped polysilicon is first deposited over the gate oxide layer. Then, Boron (B) ions are implanted into the undoped polysilicon and then rapid thermal annealing is used for activating the dopant concentration. The dopant activation concentration in such polysilicon gate of the conventional PMOS transistor will not be greater than 1×10²⁰/cm³. On the other hand, FIGS. 19-21 illustrate the exemplary manufacturing processes for the PMOS transistor according to the present invention, the detail of which is skipped since they are similar to FIGS. 16-18, but the dopant type in the epitaxial silicon gate of the PMOS transistor is different from that in the epitaxial silicon gate of the NMOS transistor. The dopant activation concentration in such epitaxial silicon gate of the PMOS transistor according to the present invention will be greater than 1×10²⁰/cm³.

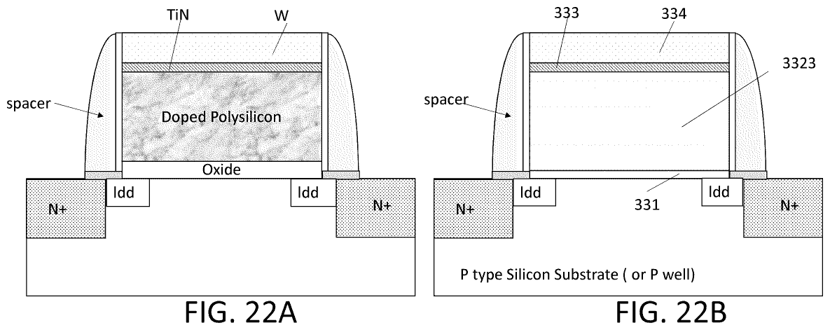

FIGS. 22A and 22B illustrates the comparison between the polysilicon gate transistor according to the conventional process (FIG. 22A) and the polysilicon gate transistor according to the process invention (FIG. 22B). The high dopant activation concentration of the in-situ doped N+/P+ silicon 3322 can reduce polysilicon depletion effect, reduce the thickness of the gate dielectric layer 331, and improve Ion and gate control capability. In summary, the present invention solves the dopant activation concern in the conventional polysilicon gate transistor, and increases dopant activation concentration in silicon gate of the NMOS transistor and PMOS transistor not less than 4×10²⁰/cm³ (N+) and 1×10 ²⁰/cm³ (P+). Such high dopant activation concentration can reduce polysilicon depletion effect, reduce the thickness of the gate dielectric layer, and improve Ion and gate control capability. The present invention could be applied to all transistors with the silicon gate, such as, planar transistor, fin-structure transistor, GAA transistor, etc. Furthermore, such epitaxial silicon gate transistors could not only be applied to logic circuit, but also applied to the peripheral circuit of semiconductor memory, such as DRAM. Moreover, the present invention could be applied to other semiconductor material, such as SiGe, SiC, or GaN, etc., used in the gate structure of the MOS transistor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor transistor comprising:
a source region, a drain region, and a channel region between the source region and the drain region; and
a gate region over the channel region, wherein the gate region comprises a gate dielectric layer on the channel region and an epitaxial doped semiconductor layer over the gate dielectric layer.

2. The semiconductor transistor in claim 1, wherein the semiconductor transistor is a NMOS transistor, the epitaxial doped semiconductor layer is an epitaxial doped silicon layer, and the dopant activation concentration of the epitaxial doped silicon layer is not less than 3×10²⁰/cm³.

3. The semiconductor transistor in claim 1, wherein the semiconductor transistor is a PMOS transistor, the epitaxial doped semiconductor layer is an epitaxial doped silicon layer, and the dopant activation concentration of the epitaxial doped silicon layer is not less than 8×10¹⁹/cm³.

4. The semiconductor transistor in claim 1, wherein the gate region further comprises a TiN layer and a Tungsten layer over the epitaxial doped semiconductor layer.

5. The semiconductor transistor in claim 4, wherein the semiconductor transistor is a transistor in a peripheral circuit of DRAM.

6. A method to manufacture a semiconductor transistor, comprising:
preparing a semiconductor substrate;
forming a gate region within the semiconductor substrate, wherein the gate region comprises an epitaxial doped semiconductor layer; and
forming a source region and a drain region, wherein the gate region is between the source region and the drain region.

7. The method of claim 6, wherein the step of forming the gate region comprises:
forming a gate dielectric layer over the semiconductor substrate;
depositing an amorphous semiconductor layer over the gate dielectric layer;
annealing the amorphous semiconductor layer for recrystallization;
selectively growing the epitaxial doped semiconductor layer based on the recrystallized semiconductor layer; and
thermally annealing the epitaxial doped semiconductor layer.

8. The method of claim 7, wherein the grain size of the recrystallized semiconductor layer is 1˜2 um.

9. The method of claim 7, wherein the step of forming the gate region further comprises:
forming a TiN layer over the epitaxial doped semiconductor layer; and
forming a Tungsten layer of the TiN layer.

10. The semiconductor transistor in claim 6, wherein the semiconductor transistor is a NMOS transistor, the epitaxial doped semiconductor layer is an epitaxial doped silicon layer, and the dopant activation concentration of the epitaxial doped silicon layer is not less than 3×10²⁰/cm³.

11. The semiconductor transistor in claim 6, wherein the semiconductor transistor is a PMOS transistor, the epitaxial doped semiconductor layer is an epitaxial doped silicon layer, and the dopant activation concentration of the epitaxial doped silicon layer is not less than 8×10¹⁹/cm³.

12. A semiconductor transistor comprising:
a source region, a drain region, and a channel region between the source region and the drain region; and
a gate region over the channel region, wherein the gate region comprises a gate dielectric layer on the channel region and a highly doped semiconductor layer over the gate dielectric layer;
wherein a gate length of the gate region is not greater than 150 nm, and wherein the highly doped semiconductor layer within the gate length is a single crystalline layer, or along the gate length the highly doped semiconductor layer includes no more than three semiconductor grains.

13. The semiconductor transistor in claim 12, wherein the semiconductor transistor is a NMOS transistor, the highly doped semiconductor layer is a highly doped silicon layer, and the dopant activation concentration of the highly doped silicon layer is not less than 3×10²⁰/cm³.

14. The semiconductor transistor in claim 12, wherein the semiconductor transistor is a PMOS transistor, the highly doped semiconductor layer is a highly doped silicon layer, and the dopant activation concentration of the highly doped silicon layer is not less than 8×10¹⁹/cm³.

15. A semiconductor transistor structure comprising:
a source region, a drain region, and a channel region between the source region and the drain region; and
a gate region over the channel region, wherein the gate region comprises a gate dielectric layer on the channel region and a doped semiconductor layer over the gate dielectric layer;
wherein in the event the semiconductor transistor is a NMOS transistor, the dopant activation concentration of the epitaxial doped silicon layer is not less than 3×10²⁰/cm³, or in the event semiconductor transistor is a PMOS transistor, the dopant activation concentration of the epitaxial doped silicon layer is not less than 8×10¹⁹/cm³.

16. The semiconductor transistor in claim 15, wherein the doped semiconductor layer is a doped silicon layer or a doped SiGe layer.

17. The semiconductor transistor in claim 15, wherein the semiconductor transistor is a transistor in a peripheral circuit of a DRAM chip.
